(19) United States
(12) Patent Application Publication
(10) Pub. No.: US 2016/0024648 A1
(43) Pub. Date: Jan. 28, 2016

(54) Process for making triple graded CVC-CVD-CVC silicon carbide products

(71) Applicant: Lauren Bolton, Lihue, HI (US)

(72) Inventor: Lauren Bolton, Lihue, HI (US)

(21) Appl. No.: 14/121,049

(22) Filed: Jul. 24, 2014

(51) Int. Cl. C23C 16/32; C23C 16/01

(52) U.S. Cl. CPC C23C 16/325; C23C 16/01

(57) ABSTRACT

A chemical vapor composite process for making high quality silicon carbide suitable for optical and structural components with low intrinsic stress and high thermal stability. In the CVC process solid micron-scale silicon carbide particles are incorporated into a high purity chemical vapor stream and injected into a high temperature furnace. Three layers of silicon carbide are vapor deposited on the graphite mandrel. The first layer is a sacrificial layer, deposited utilizing the chemical vapor composite process. The second layer is the optical cladding CVD layer, which is deposited by continuous deposition of the high purity chemical precursor without the silicon carbide particles. This layer is ground and polished to a high optical finish. The third layer is the bulk of the mirror structure and deposited via the CVC SiC process as described above. The thickness of this structural layer is determined by the product's geometrical and structural requirements.

### FEDERAL SUPPORTED RESEARCH

The present invention was made in the course of work under contract Number HQ0006-05-D-0006 and the United States Government has rights in the invention.

### FIELD OF THE INVENTION

The present invention relates to stress-free, thermally stable silicon carbide (SiC) composites, and in particular to SiC composite optics (mirrors).

### BACKGROUND OF THE INVENTION

### Silicon Carbide

Silicon carbide, also known as carborundum, is a rare earth element, existing naturally in minute quantities only in the form of moissanite in certain types of meteorites and corundum deposits and kimberlite. Virtually all the silicon carbide sold in the world is synthetic. Early experiments in the synthesis of silicon carbide were conducted during the 1800's using a variety of source materials and processes. Wide scale production of silicon carbide as we know it today is credited to Edward Goodrich Acheson in 1890. Acheson patented the method for making silicon carbide powder and developed the electric batch furnace by which SiC is still made today. Acheson formed The Carborundum Company to manufacture SiC in bulk, initially for use as an abrasive, although the material he formed varied in purity. Pure silicon carbide can be made by three primary processes and one patented process. The first is known as the Lely method whereby silicon carbide powder is sublimated onto substrates comprised of the same constituents and redeposited at cooler temperatures to form SiC. The second method of preparation is by thermal decomposition of a polymer, poly(methylsilane), under an inert atmosphere at low temperatures. The third method, known as the chemical vapor deposition process (CVD), involves thermal decomposition of a high purity chemical precursor on a substrate surface. The fourth method of production is a process patented by Trex Enterprises Corporation called the chemical vapor composite (CVC®) process.

Silicon carbide exists in a large number of crystalline forms all of which are variations of the same chemical compound. Alpha silicon carbide (α-SiC), the most common form of silicon carbide, has a hexagonal crystal structure. Silicon carbide produced using CVD processes typically have a face-centered cubic crystal structure referred to as a beta silicon carbide. Silicon carbide produced using the CVC process is typically a mixture of alpha silicon carbide and beta silicon carbide.

Silicon carbide has a theoretical density of 3.21 g/cm³ and is chemically inert. SiC has a high melting point (2730° C.), low coefficient of thermal expansion (CTE) and no phase transitions that would cause discontinuities in thermal expansion, making it an ideal material for high temperature and optical applications.

The Applicant's employer (Trex Enterprises Corporation) is the assignee of two patents (U.S. Pat. Nos. 5,154,862 and 5,348,765, both of which are incorporated by reference herein) covering a unique process for making silicon carbide, known as the CVC process or the CVC SiC® process (CVC® and CVC SiC® are registered trademarks of Trex Enterprises Corporation). In CVC SiC an aerosol of solid micron-scale SiC particles is entrained within a reactant chemical vapor precursor and injected into a high temperature furnace. The aerosol mixture reacts at high temperature to form solid, high purity CVC SiC on a heated graphite substrate. The chemical process is analogous to chemical vapor deposition (CVD), which similarly uses a chemical vapor precursor, but without the added SiC particles. The key consequence of adding solid particles to the reaction stream is a unique grain structure that results in a fully dense, virtually stress-free material. Thus, CVC SiC can be:
grown over 5× faster than conventional CVD
scaled to very large sizes (up to 1.45 m diameter)
manufactured thickness of at least 63 mm
deposited to near net shape
machined to thin dimensions with reduced risk of fracture

Other notable advantages of CVC silicon carbide include very high stiffness, high thermal conductivity, low thermal expansion, low density and high specific stiffness.

### Lightweight Mirror Materials

An important application for CVC silicon carbide is in the production of lightweight optics and optical systems. Lightweight optics are utilized in space and airborne applications for detection, surveillance, imaging and tracking. These mirrors typically consist of an optical quality facesheet reinforced with a ribbed backside structure to maintain mirror stiffness. The ribbed structure is produced by grinding, milling or in some way machining material away. The extensive amount of machining required to lightweight a mirror, compounded by the amount of bulk material that is ultimately unused, makes the manufacturing and fabrication costs of lightweighted optics very high. As a solution, if the mirror material has a high stiffness to weight ratio (ie: specific stiffness) then the thickness of the backside structure can be significantly reduced or eliminated, thereby reducing the cost.

Mirror materials with the highest specific stiffness are beryllium (155 MPa-m³/kg) and SiC (143 Mpa-m³/kg). Beryllium (Be) has been utilized extensively in airborne optics, however it is highly toxic and expensive to procure and fabricate. SiC, particularly CVC SiC, is a highly desirable alternative to beryllium as it solves a number of limitations and problems posed by Be components:
CVC SiC, while nearly as stiff as Be, is much more thermally stable, thus allowing CVC SiC optics to perform in low altitude, aggressive trajectory flight.
Components can be fabricated from CVC SiC blanks in 4-6 weeks versus a Be blank which requires 8-9 months.
CVC SiC is non-toxic thereby eliminating the costs associated with managing the environmental, health, and safety procedures required in the manufacture of components from Be.
CVC SiC is resistant to ionizing radiation, unlike Be.
Unlike Be, CVC SiC will not corrode.

SiC also has the advantage over other mirror materials, including aluminum and glass, which are significantly less stiff than either beryllium or SiC.

To date Trex has produced CVC SiC mirror blanks with typical surface figure values of better than λ/10 P-V at 632.8 nm, surface roughness values of less than 5 Å RMS, and an aspect ratio performance of 24:1 (aspect ratio is the diameter to thickness ratio).

Although CVC SiC optics polish extremely well the polished surface has been observed, on rare occasions, to have micron scale imperfections. The size and geometry of these imperfections suggest that the solid SiC particles pulled out of the silicon carbide matrix during the polishing process. It is unknown whether particle pull-out is initiated by a specific polishing methodology or process as not all polishing houses observe this phenomenon (those that have given anecdotal evidence do not observe pull-out consistently). Particle pull-out results in a microscopic void (dig) in the mirror's optical surface. Such surface defects may result in light scattering, undesired diffraction patterns, loss of contrast and stray light, which can degrade image quality and affect overall optical system performance. While the occurrence of particle pull out is rare, the potential result can be significant.

What is needed is an improved process for making silicon carbide mirrors for airborne and space-based optics utilizing CVD and CVC technology in order to circumvent the possibility of particle pull-out.

### SUMMARY OF THE INVENTION

The present invention provides a chemical vapor composite deposition process for fabricating low stress, thermally stable, highly polishable silicon carbide products. In preferred embodiments a graphite substrate is prepared having the desired shape of the resultant silicon carbide deposit. The substrate is placed in a high temperature chemical vapor reactor. Three layers of silicon carbide are vapor deposited on the graphite substrate. The first layer is a sacrificial layer, deposited using the chemical vapor composite (CVC) process in which an aerosol of solid micron-scale SiC particles is entrained within a reactant chemical vapor precursor and injected into the high temperature reactor to form a high purity, solid CVC SiC foundation upon which the second and third layers will be deposited. The second layer is a highly polishable CVD SiC material that is formed by continuous deposition of the high purity chemical precursors, but without the solid silicon carbide particles. This second layer is thin and thus not plagued by the inherent stress of bulk CVD SiC. Moreover, because it is deposited on top of a stress-free CVC SiC foundation, with an identical coefficient of thermal expansion, any tensile stress in the CVD layer would be further reduced. These stress mitigation design strategies result in a second layer of SiC material that can be easily ground and polished to precise optical prescriptions. The third layer comprises the bulk of the mirror structure and is deposited using the CVC SiC process. It is formed by continuous deposition of the high purity chemical precursors and resuming the incorporation of the micron-scale solid silicon carbide particles. The third layer can be as thick as needed to meet the geometric, strength and structural requirements of the product's design. Since deposition of the three layers is absolutely continuous (no change in gas flow rates, temperature or pressure) the grain structure of each layer transitions seamlessly into the next (confirmed by microscopic evaluation).

After the reactor has been cooled down to approximately room temperature the three-layered/triple-graded CVC-CVD-CVC silicon carbide deposition is easily removed in a single piece from the substrate. The first CVC SiC layer is machined away, exposing the pristine second layer of CVD silicon carbide. This second layer is ground and polished in accordance with the required surface specifications. The third CVC SiC layer—having virtually no stress but with all the excellent thermal and mechanical properties of CVD—may be ground on the side opposite the polished side to meet the dimensional and structural requirements of the final product.

The thickness of each respective layer can be easily controlled by varying the deposition time and gas flow rates. Higher gas flow rates and longer deposition times result in thicker layers. In preferred embodiments the high purity chemical precursor gas is methyltrichlorosilane (MTS) and flow rates range from 2-7 standard liters per minute (slpm); hydrogen flow rates range from 2-40 slpm; powder feed rates range from 0-4 grams per hour; temperatures range from 1400-1500° C.; pressures range from 200-300 torr.

The purpose of varying the layer thicknesses would be to: 1) meet specific product requirements, and/or 2) minimize post-production machining costs. For example, for an 8-inch diameter mirror with a final overall thickness of 0.275″ and a radius of curvature less than 200 mm, the layer thicknesses of the as-deposited disc could be approximately 0.017 inch for the first sacrificial layer, 0.035 inch for the second polishable layer and 0.300 inch for the third structural layer.

The present invention can be applied to produce a CVC-CVD-CVC meniscus to replace lightweighted, ribbed-backed optics in space and airborne systems.

### BRIEF DESCRIPTION OF THE DRAWINGS

FIG. 1 is a drawing of the preferred process for practicing the present invention.

FIG. 2 is a drawing showing three layers of silicon carbide deposited on a graphite mandrel.

FIGS. 3A and 3B show a sample of a curved substrate, and a substrate for the production of two mirrors in a single deposition.

### DETAILED DESCRIPTION OF PREFERRED EMBODIMENTS

### Applicant's CVC-CVD-CVC Process

As explained in the background section, Applicant's employer has developed, patented and trademarked its CVC process for making stress-free, thermally stable, high purity silicon carbide products. CVD processes are well known and similar to the Applicant's CVC process except that micron-scale solid particles are not used in CVD silicon carbide. The present invention marries the superior optical and thermo-mechanical properties of CVD SiC and the virtually stress-free grain structure of CVC SiC to produce silicon carbide products far superior to products produced by CVD alone.

### The CVC Process

To make CVC SiC an aerosol of solid micron-scale SiC particles is entrained within a reactant chemical vapor precursor and injected into a high temperature furnace. The aerosol mixture reacts at high temperature to form high purity solid CVC SiC on a heated graphite substrate. The chemical process is analogous to chemical vapor deposition (CVD), which similarly uses a chemical vapor precursor but without the added SiC particles. The significant drawback of conventional CVD is the high internal stress caused by its anisotropic, columnar grain structure. This inherent stress problem is solved by the CVC process wherein an equiaxial grain structure is produced.

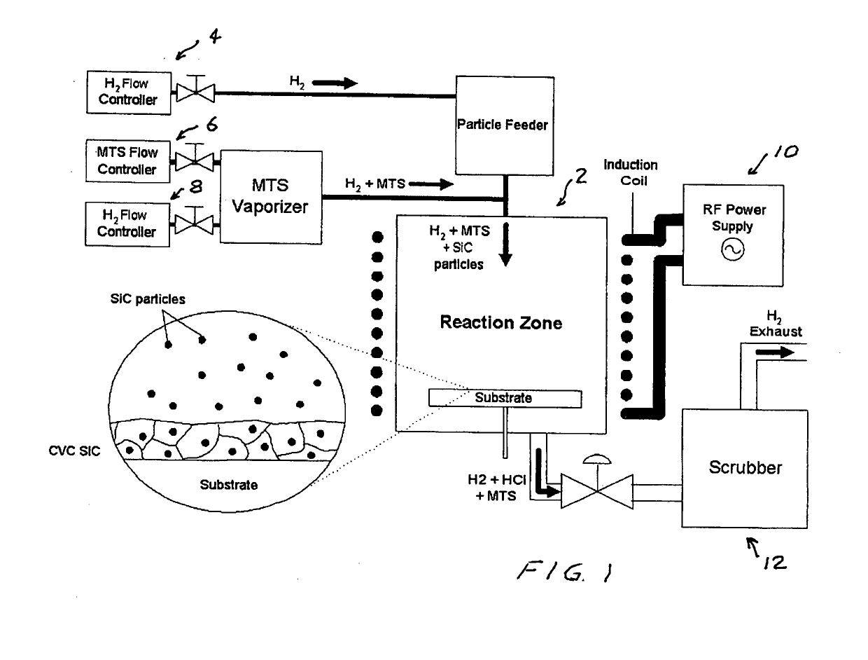

Details of the CVC SiC process are shown in FIG. 1. Particle flow is controlled by the particle feeder and carried into the reactor 2 by a stream of hydrogen which is controlled by an H₂ flow controller 4. MTS and H₂ flow are controlled by MTS flow controller 6 and H₂ flow controller 8. Reactor temperature is maintained by RF power supply 10. Exhaust is neutralized by scrubber system 12.

The overall chemical reaction involves decomposition of the precursor species methyltrichlorosilane (CH₃SiCl₃ or “MTS”) to SiC and hydrochloric acid (HCl):

CH₃SiCl_{3(g)}=SiC₍ₛ₎+3 HCl_{(g)} (1)

While not apparent in the overall reaction, the use of hydrogen (H₂) as a carrier gas is essential to the formation of high quality SiC; H₂ is produced in the formation of key gas phase intermediates such as vinyl gas (C₂H₄) and acetylene (C₂H₂), and then consumed during the deposition of Si onto the surface. The HCl waste product is removed from the exhaust stream with water shower scrubbers, and neutralized with sodium hydroxide (NaOH):

HCl_{(aq)}+NaOH_{(aq)}=H₂O₍ₗ₎+NaCl_{(aq)} (2)

The resulting salt water is pumped into an injection well at Applicant's employer's facility on Kauai in Hawaii where it is released into the natural saline layer in the island's water table.

### Triple Graded CVC-CVD-CVC Mirrors

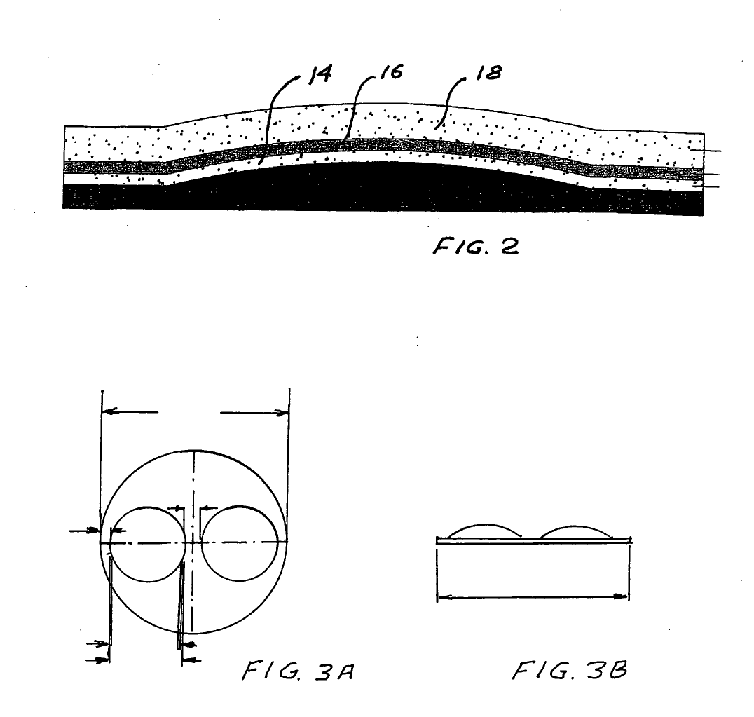

The present invention referred to as Applicant's CVC-CVD-CVC SiC tripled-graded SiC material is built upon the basic CVC SiC process described above. Preferred embodiments of the process are ideal for producing stress-free thermally stable silicon carbide optics. Three seamless layers of silicon carbide are deposited successively in a single deposition run as shown in FIG. 2.

The first layer 14 is a thin CVC SiC layer called the sacrificial layer. The second layer 16 is a thin CVD SiC layer called the optical cladding layer. The third and final layer 18 is called the structural layer. The sacrificial layer is the stress-free foundation upon which the optical cladding and structural layers are built. The sacrificial layer is machined away to expose the pristine optical cladding layer. The optical cladding layer thickness is determined by the mirror prescription and surface quality requirement. The structural layer comprises the remaining bulk thickness of the optic.

The layer thicknesses are dependent on deposition time and gas flows (higher gas flow rates and longer deposition times result in thicker layers): MTS flow rates range from 2-7 slpm; hydrogen flow rates range from 2-40 slpm; powder feed rates range from 0-4 grams/hour; temperatures range from 1400-1500° C.; pressures range from 200-300 torr. Applicant has produced high quality optics using the process conditions provided above, but believe that parameters outside these ranges and ranges of parameters normally used in CVC or CVD processes could also produce good to excellent results. For example Applicant has experimented with process parameters utilizing temperatures as low as 1350° C. and pressures up to 760 torr.

The runs described above were deposited on a single mandrel, either flat or curved. A flat substrate is a simple flat disc of varying thicknesses (0.25-2″). An example of a curved substrate is shown in FIGS. 2 and 3A and 3B. The shape of the mandrel curve and the width of the flat lip are determined by the shape, size and prescription of the mirror to be manufactured and the reactor in which the deposition will be conducted. Applicant has experimented with three reactors having different sized hot zones: 16 inch diameter, 18 inch diameter and 60 inch diameter, respectively. These reactors, and reactors of other sizes, can be utilized to produce SiC products using the techniques of the present invention.

In addition to single yield operations, this process could also be utilized in a high throughput regime in which more than one article is manufactured in a single deposition run. High throughput yield can be accomplished in a variety of ways. Two of the ways the Applicant has successfully done this in the past was to use: 1) a few single mandrels in one run, or 2) one large single mandrel with multiple yield points. An example of a substrate for method 2 is shown in FIGS. 3A and 3B.

Each “bump” on the substrate yields one mirror, therefore two mirrors are made using this particular substrate. Applicant employed the high throughput yield process in their 16 inch reactor to manufacture CVC-CVD-CVC SiC HALO secondary mirrors. The mandrel that was designed and commissioned yielded 7 mirror blanks.

The CVC-CVD-CVC SiC process is suitable for making optics that are 0.25 inch diameter up to 60″ diameter in the reactors available to Applicant. Mirror blanks that are larger than 25-inch diameter are produced using a single substrate. Mirror blanks that are less than 25-inch diameter can be manufactured using either a single substrate or a high throughput substrate with multiple yield points. The number of mirror blanks that can be yielded via high throughput would depend on the overall diameter of the mirror blank and the reactor used to deposit them.

### Applicant's Test Runs

Applicant has conducted test runs to prove the practicality of the present invention, marrying the thermo-mechanical properties and polishability of CVD with the low stress advantage of CVC. The first step was to develop a dual grade CVD-CVC material, where CVD SiC was deposited first, followed by CVC SiC. The thickness of each layer was experimentally varied, with CVC always being thicker. Test polishing was done on the CVD layer. This dual grade material development effort was met with mixed success. Hairline fractures observed in the initial CVD layer, particularly at increased thickness, were due in part to the inherent stress of CVD SiC and perhaps to a CTE mismatch between silicon carbide and the graphite substrate. To help preserve the integrity of the CVD layer Applicant developed their triple-graded material consisting of an initial CVC SiC layer, followed by a particle-free CVD layer, and then finished by a final CVC layer. The initial CVC layer served as a stress-free sacrificial medium that would be machined off to expose the pristine encapsulated CVD material, which could then be polished to a high optical finish.

A successful production run was recently conducted with the triple-graded SiC. The deposit released from the graphite mandrel intact and crack-free. Four samples were core drilled from the blank for cross-sectional microstructural analysis. Four additional samples were core drilled and the initial CVC layer ground off for test polishing with excellent results.

Benefits of the technology include:
1. stress-free, fracture-free initial deposit
2. preservation of pristine, highly polishable CVD cladding layer
3. seamless transition between all three layers, no delamination effects

### Other Product Applications

To date the CVC-CVD-CVC SiC process has been used to manufacture beryllium-replacement optics in telescopes. However, in a broader scope, this process can be used to manufacture mirrors for any application where high thermal conductivity, high thermal stability (in high temperature or cryogenic conditions), low thermal expansion, low density and high specific stiffness are required.

By extension, the process of the present invention can be used to manufacture:
optical structure components (telescope structure components) that would have the same requirements listed above
ceramic components for space, semiconductor, nuclear or military applications
   space: optics, optical structures, missile nose cones, DACS liners (divert attitude control systems), shuttle tiles, wing leading edges, thermal propulsion components
   semiconductor: process components for wafer fabrication manufacturing
   nuclear: fuel cladding rods
   military: armor (vehicle or personal), gun barrel liners, missile/tactical optics and associated optical structures
lens molds or other similar surface replication applications.

### Benefits of the Present Invention

Benefits of the present invention include:
1. Because the CVC SiC to CVD SiC to CVC SiC deposition processes are continuous a seamless chemical bond exists between the layers. Consequently, there is no risk of delamination of the layers.
2. Near net shape forming of the optical surface, including exotic geometries such as aspheres, off-axis aspheres, nose cones, nozzles, wing leading edges, and frustums.
3. Optical finish of CVD SiC is not subject to particle pull-out which can result in light scattering.
4. The first layer of the triple-graded material retains the low residual stress advantage of CVC SiC. The second CVD SiC layer can be made comparatively thin (approximately 1-2 mm) and still meet the demanding specifications of high quality optical surfaces; this avoids the high stress of thick CVD SiC material. The third CVC SiC layer can be made to a specified thickness to meet the required geometric and structural requirements of the desired application.
5. Other advantages of CVD SiC are retained, including high specific stiffness, high thermal conductivity, and low thermal expansion.
6. Small optical components, including lens molds for surface replication, can be made with CVD SiC layers greater than 4 mm.

### Variations

The above described embodiments of the present invention have been described in detail. Persons skilled in the art will recognize that many variations of the present invention are possible. Therefore, the scope of the present invention should not be limited to the above described preferred embodiments, but by the appended claims and their legal equivalence.

What is claimed is:

1. A chemical vapor composite (CVC) process for fabricating stress-free, thermally stable silicon carbide product utilizing the following steps:
A) preparing a substrate with a flat or near net shaped surface so as to produce the desired geometry in the deposited silicon carbide,
B) placing the substrate in a high temperature chemical vapor reactor,
C) vapor depositing a first layer, a second layer and a third layer of silicon carbide on the mandrel wherein:
1) the first layer is a sacrificial layer utilizing the chemical vapor composite process (CVC) in which micron scale silicon carbide particles are incorporated into a high purity chemical vapor stream and injected into a high temperature furnace, wherein the aerosol mixture reacts at high temperature to form a solid CVC SiC layer that forms the stress-free foundation upon which the subsequent optical cladding layer is deposited.
2) the second layer is the optical cladding CVD layer which is deposited by continuous deposition of the high purity chemical precursor without the silicon carbide particles to provide a surface that can be ground and polished to a high optical finish and
3) the third layer is the bulk of the mirror structure and is deposited via the CVC SiC process, wherein the thickness of this structural layer is determined by the product's final geometrical and structural requirements.
D) removing the triple-graded silicon carbide deposit from the substrate,
E) grinding away the sacrificial layer to expose the optical cladding layer;
F) grinding and polishing the optical cladding layer in accordance with the desired surface requirements.

2. The process as in claim 1 and further comprising a step of grinding the away a portion of the third layer to comply with desired product shape and weight specification.

3. The process as in claim 1 wherein the silicon carbide product is an optical structure.

4. The process as in claim 3 wherein the silicon carbide product is a mirror.

5. The process as in claim 1 wherein the chemical vapor composite process includes incorporation of tiny silicon carbide particles into a high purity silicon carbide chemical precursor gas stream,

6. The process as in claim 5 wherein the precursor gas stream comprises methyltrichlorosilane (MTS) and the tiny silicon carbide particles have a maximum dimension of about 50 micron and are carried by a hydrogen gas stream.

7. The process as in claim 5 wherein layer thicknesses are controlled by controlling the deposition time and gas flows.

8. The process as in claim 6 wherein MTS flow rates may range from 2-7 standard liters per minute (slpm); hydrogen flow rates may range from 2-40 slpm; powder feed rates may range from 0-4 grams per hour; temperatures may range from 1400-1500° C.; pressures may range from 200-300 torr.
